(19) United States
(12) Patent Application Publication
(10) Pub. No.: US 2012/0043987 A1
(43) Pub. Date: Feb. 23, 2012

(54) Probe Card for Testing Semiconductor Devices and Vertical Probe Thereof

(75) Inventors: Choon Leong Lou, Hsinchu City (TW); Chih Kun Chen, Hsinchu City (TW)

(73) Assignee: STAR TECHNOLOGIES INC., Hsinchu City (TW)

(21) Appl. No.: 12/861,183

(22) Filed: Aug. 23, 2010

(51) Int. Cl. G01R 31/00

(52) U.S. Cl. 324/756.03

(57) ABSTRACT

A vertical probe for testing semiconductor devices includes a bottom contact and a top contact stacked on the bottom contact in a substantially linear manner. In one embodiment of the present invention, the bottom contact includes a plurality of first wave springs stacked one on top of another in a crest to crest manner, the bottom contact has a bottom opening configured to contact a device under test, and the wave spring is configured to provide a vertical displacement for relieving the stress generated as the vertical probe contacts the device under test, wherein the width of the top contact is greater than the width of the bottom contact.

### BACKGROUND OF THE INVENTION

1. Technical Field

The present invention relates to a probe card for testing semiconductor devices, and more particularly, to a probe card for testing semiconductor devices having at least one wave spring configured to provide vertical displacement for relieving the stress generated as the vertical probe contacts the device under test.

2. Background

Generally, it is necessary to test the electrical characteristics of semiconductor devices at the wafer level to check whether the semiconductor device satisfies the product specification. Semiconductor devices with electrical characteristic satisfying the specification are selected for the subsequent packaging process, while the other devices are discarded to avoid additional packaging cost. Another electrical property test is performed on the semiconductor device after the packaging process is completed to screen out substandard devices and increase the product yield.

There are two major types of probes according to the prior art, i.e., the cantilever probe and the vertical probe for semiconductor device. The cantilever probe provides appropriate vertical displacement when the probe tip contacts a semiconductor device under test via a cantilever contact structure designed to prevent the semiconductor device under test from being exposed to excessive probe pressure applied by the probe tip. However, the cantilever contact structure occupies a large planar space in a matrix array probing, which constrains the cantilever probe from being arranged in a fine pitch manner corresponding to a semiconductor device with high density of pins, and therefore such arrangement cannot be applied to the testing of the semiconductor devices with high density of pins.

The vertical probe for semiconductor device testing offers the vertical displacement required by the probe tip to contact the semiconductor device under test using the deformation of the probe body itself, and can be arranged in a fine pitch manner corresponding to the semiconductor devices under test with high density of pins. However, if the deformation of the probe body is large enough that adjacent probes may contact each other, this may cause short circuits or collisions.

U.S. Pat. No. 5,977,787 discloses a vertical probe for semiconductor device assembly for checking the electronic properties of semiconductor devices. The vertical probe for semiconductor device assembly includes a buckling beam, an upper plate and a bottom plate. The vertical probe is used to contact the pad of the device under test to build a path for propagating the test signal, and bends itself to relieve the stress generated as the probe contacts the device under test. The upper plate and the bottom plate have holes to hold the buckling beam, and the hole of the upper plate deviates from the hole of the bottom plate, i.e., it is not positioned in a mirror image manner. In addition, frequent bending of the vertical probe for semiconductor device is likely to generate metal fatigue and the lifetime of the vertical probe is thereby limited.

U.S. Pat. No. 5,952,843 discloses a vertical probe for semiconductor device assembly for checking the electronic properties of semiconductor devices. The vertical probe for semiconductor device assembly includes a bend beam, an upper plate and a bottom plate. The vertical probe has an S-shaped bend portion configured to relieve the stress generated as the probe contacts the device under test. In addition, the upper plate and the bottom plate have holes to hold the buckling beam, and the holes of the upper plate and the bottom plate are positioned in a mirror image manner, without deviation from each other.

U.S. Pat. No. 4,027,935 discloses a contact for a contactor assembly having a pivotable end and a pre-curved center section, which deflects in combination with the pivoting of the pivotable end to provide minimal forces on contact pads when a force is applied between the pad and the contactor assembly. The pre-curved center section has a large radius and is arranged such that the pivotable end and the contacting end of the contact are offset from one another within the plane including the radius of the center section so that the deflection direction is predetermined and deflection forces are reduced.

### SUMMARY

One aspect of the present invention provides a vertical probe for testing semiconductor devices having at least one wave spring configured to provide vertical displacement for relieving the stress generated as the vertical probe contacts the device under test and a probe card for testing semiconductor devices using the same.

A vertical probe for semiconductor device testing according to this aspect of the present invention comprises a bottom contact and a top contact stacked on the bottom contact in a substantially linear manner. In one embodiment of the present invention, the bottom contact includes a plurality of first wave springs stacked one on top of another in a crest to crest manner, the bottom contact has a bottom opening configured to contact a device under test, and the wave spring is configured to provide a vertical displacement for relieving the stress generated as the vertical probe contacts the device under test, wherein the width of the top contact is greater than the width of the bottom contact.

Another aspect of the present invention provides a vertical probe for testing semiconductor devices comprising a bottom contact and a top contact stacked on the bottom contact in a substantially linear manner. In one embodiment of the present invention, the bottom contact includes a first wave spring having a plurality of spring turns, each spring turn includes at least one crest portion and at least one trough portion, adjacent pairs of spring turns contact one another in a crest to crest manner, the first wave spring has a bottom opening configured to contact a device under test, and the first wave spring is configured to provide a vertical displacement for relieving the stress generated as the vertical probe contacts the device under test, wherein the width of the top contact is greater than the width of the bottom contact.

Another aspect of the present invention provides a probe card for testing semiconductor devices comprising a guiding member having a plurality of holes, a circuit board positioned on the guiding member and having a plurality of contact sites facing the holes, and a plurality of vertical probes positioned in the holes. In one embodiment of the present invention, each vertical probe includes a bottom contact having at least one wave spring configured to contact a device under test, and the wave spring is configured to provide a vertical displacement for relieving the stress generated as the vertical probe contacts the device under test.

The conventional vertical probe for semiconductor device testing uses a crown probe tip, which damages the solder ball of the device under test as the vertical probe contacts the device under test. For example, as a four-claw crown probe tip contacts the solder ball, a four-claw imprint is formed on the solder ball because the stress generated as the vertical probe contacts the device under test is applied to a small contact area.

In contrast, the disclosure of the present invention uses the wave spring with the bottom contact serving as the probe tip, and the wave spring contacts the solder ball with a larger ring-shaped contact area so as to reduce the damage of the vertical probe on the solder ball. In addition, the wave springs are stacked one on top of another in a crest to crest manner, and the current can flow through the connected crest portions from one wave to another wave, i.e., there are multiple paths for the current, rather than a single coil flowing path, which will generate inductance effect and influence the electrical measurement.

The conventional cantilever probe cannot be applied to semiconductor devices with high-density pads since it requires a lateral space to receive the lateral cantilever. In contrast, the vertical probe for semiconductor device testing of the present application does not need the lateral space for the lateral cantilever, and can provide variable contact force and be applied to the semiconductor devices with high-density pads of very small pitch.

In addition, the conventional vertical probe for semiconductor device testing uses the deformation of the probe body itself to provide vertical displacement for relieving the stress generated as the probe contacts the device under test, but the adjacent probes may contact each other and cause short circuits or collisions if the deformation of the probe body is too large or there is minor misplacement of the probe body. In contrast, the vertical probe for semiconductor device testing of the present application uses the vertical wave height to relieve the stress substantially without a lateral displacement so as to prevent the vertical probes from contacting each other and causing short circuits or collisions.

The foregoing has outlined rather broadly the features and technical advantages of the present invention in order that the detailed description of the invention that follows may be better understood. Additional features and advantages of the invention will be described hereinafter, which form the subject of the claims of the invention. It should be appreciated by those skilled in the art that the conception and specific embodiment disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

The objectives and advantages of the present invention will become apparent upon reading the following description and upon reference to the accompanying drawings in which:

FIG. 1 illustrates a vertical probe according to a first embodiment of the present invention;

FIG. 2 illustrates a vertical probe according to a second embodiment of the present invention;

FIG. 3 illustrates a vertical probe according to a third embodiment of the present invention;

FIG. 4 illustrates a vertical probe according to a fourth embodiment of the present invention;

FIG. 5 illustrates a vertical probe according to a fifth embodiment of the present invention;

FIG. 6 illustrates a vertical probe according to a sixth embodiment of the present invention;

FIG. 7 illustrates a vertical probe according to a seventh embodiment of the present invention;

FIG. 8 illustrates a vertical probe according to an eighth embodiment of the present invention;

FIG. 9 illustrates a probe card according to a first embodiment of the present invention; and

FIG. 10 illustrates a probe card according to a second embodiment of the present invention.

### DETAILED DESCRIPTION

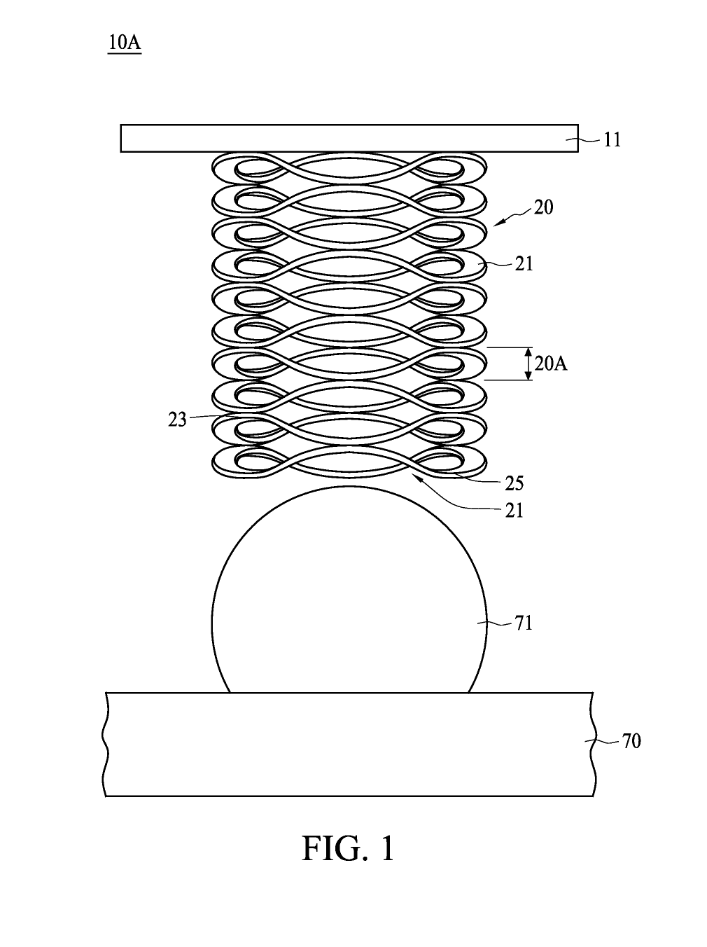

FIG. 1 illustrates a vertical probe 10A according to a first embodiment of the present invention. In one embodiment of the present invention, the vertical probe 10A comprises a bottom contact 20 and a top contact 11 stacked on the bottom contact 20 in a substantially linear manner. In one embodiment of the present invention, the bottom contact 20 has a bottom opening 21 configured to contact a ball 71 of a device under test 70, and the width of the top contact 11 is greater than the width of the bottom contact 20. In one embodiment of the present invention, the bottom contact 20 includes a plurality of wave springs 21 stacked one on top of another in a crest to crest manner. In one embodiment of the present invention, each of the wave springs 21 is formed from a single piece of conductive material and comprises a plurality of upward crest portions 23 and downward trough portions 25, and the crest portions 23 abut the trough portions 25. In one embodiment of the present invention, the wave springs 21 in an uncompressed state have a wave height 20A, i.e., the distance between the upward crest portions 23 and the downward trough portions 25, which is configured to provide a vertical displacement for relieving the stress generated as the vertical probe 10A contacts the device under test 70 in a compressed state.

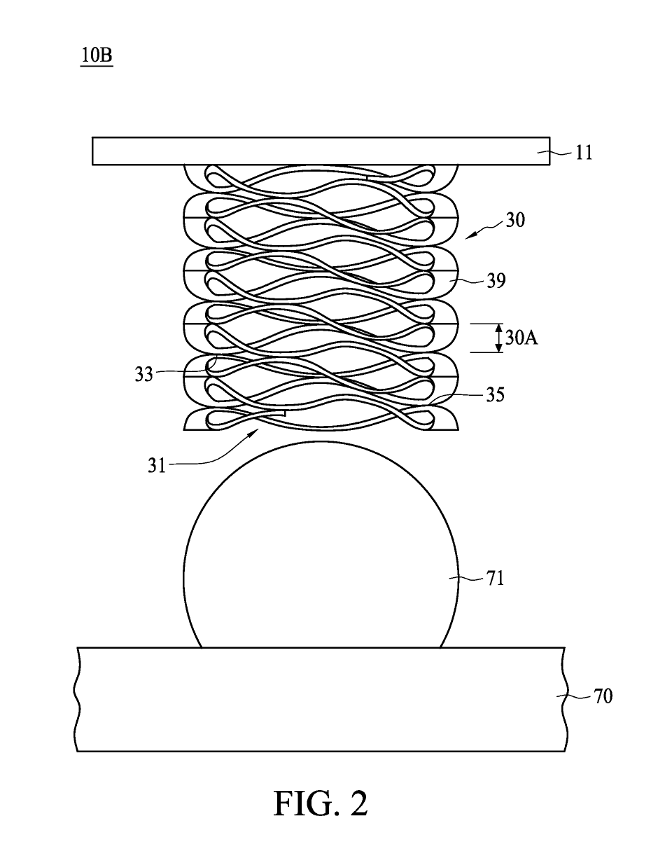

FIG. 2 illustrates a vertical probe 10B according to a second embodiment of the present invention. In one embodiment of the present invention, the vertical probe 10B comprises a bottom contact 30 and a top contact 11 stacked on the bottom contact 30 in a substantially linear manner. In one embodiment of the present invention, the bottom contact 30 has a bottom opening 31 configured to contact a ball 71 of a device under test 70, and the width of the top contact 11 is greater than the width of the bottom contact 30. In one embodiment of the present invention, the bottom contact 30 is a wave spring formed from a single piece of conductive material and having a number of spring turns 39. In one embodiment of the present invention, each spring turn 39 has successive waves formed from distinct crest portions 33 and trough portions 35, and the crest portion 33 of one spring turn 39 abuts the trough portion 35. In one embodiment of the present invention, the wave spring 30 in an uncompressed state has a wave height 30A configured to provide a vertical displacement for relieving the stress generated as the vertical probe 10B contacts the device under test 70 in a compressed state.

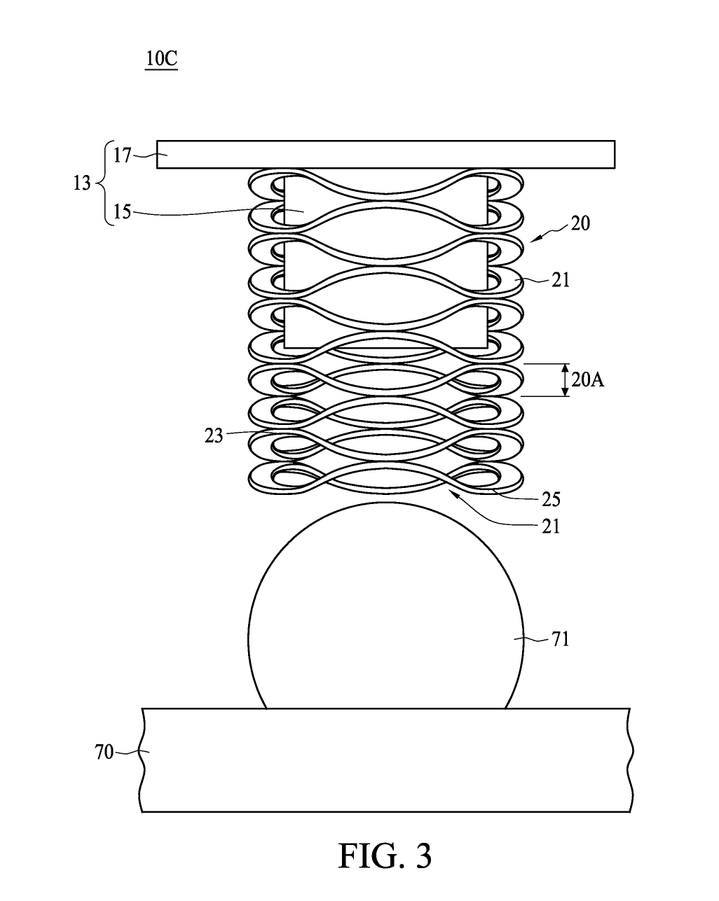

FIG. 3 illustrates a vertical probe 10C according to a third embodiment of the present invention. In one embodiment of the present invention, the vertical probe 10C comprises a bottom contact 20 and a top contact 13 stacked on the bottom contact 20 in a substantially linear manner. In one embodiment of the present invention, the bottom contact 20 has a bottom opening 21 configured to contact a ball 71 of a device under test 70, and the width of the top contact 13 is greater than the width of the bottom contact 20. In one embodiment of the present invention, the bottom contact 20 includes a plurality of wave springs 21 stacked one on top of another in a crest to crest manner. In one embodiment of the present invention, each of the wave springs 21 is formed from a single piece of conductive material and comprises a plurality of upward crest portions 23 and downward trough portions 25, and the crest portions 23 abut the trough portions 25. In one embodiment of the present invention, the wave springs 21 in an uncompressed state have a wave height 20A, i.e., the distance between the upward crest portions 23 and the downward trough portions 25, which is configured to provide a vertical displacement for relieving the stress generated as the vertical probe 10A contacts the device under test 10 in a compressed state. In one embodiment of the present invention, the top contact 13 includes a contact portion 17 on the bottom contact 20 and a guiding portion 15 in the bottom contact 20, and the guiding portion 15 is a cylinder in the wave springs 21 and is configured to guide the compression operation of the wave springs 21.

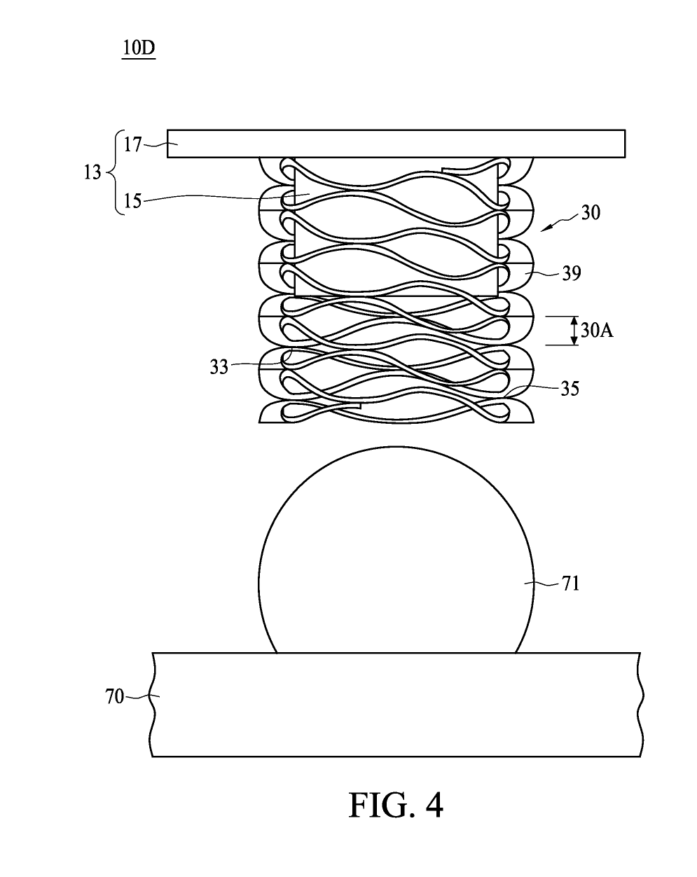

FIG. 4 illustrates a vertical probe 10D according to one embodiment of the present invention. In one embodiment of the present invention, the vertical probe 10D comprises a bottom contact 30 and a top contact 13 stacked on the bottom contact 30 in a substantially linear manner. In one embodiment of the present invention, the bottom contact 30 has a bottom opening 31 configured to contact a ball 71 of a device under test 70, and the width of the top contact 13 is greater than the width of the bottom contact 30. In one embodiment of the present invention, the bottom contact 30 is a wave spring formed from a single piece of conductive material and having a number of spring turns 39. In one embodiment of the present invention, each spring turn 39 has successive waves formed from distinct crest portions 33 and trough portions 35, and the crest portion 33 of one spring turn 39 abuts the trough portion 35. In one embodiment of the present invention, the wave spring 30 in an uncompressed state has a wave height 30A configured to provide a vertical displacement for relieving the stress generated as the vertical probe 10D contacts the device under test 70 in a compressed state. In one embodiment of the present invention, the top contact 13 includes a contact portion 17 on the bottom contact 20 and a guiding portion 15 in the bottom contact 20, and the guiding portion 15 is a cylinder in the wave springs 21 and is configured to guide the compression operation of the wave springs 21.

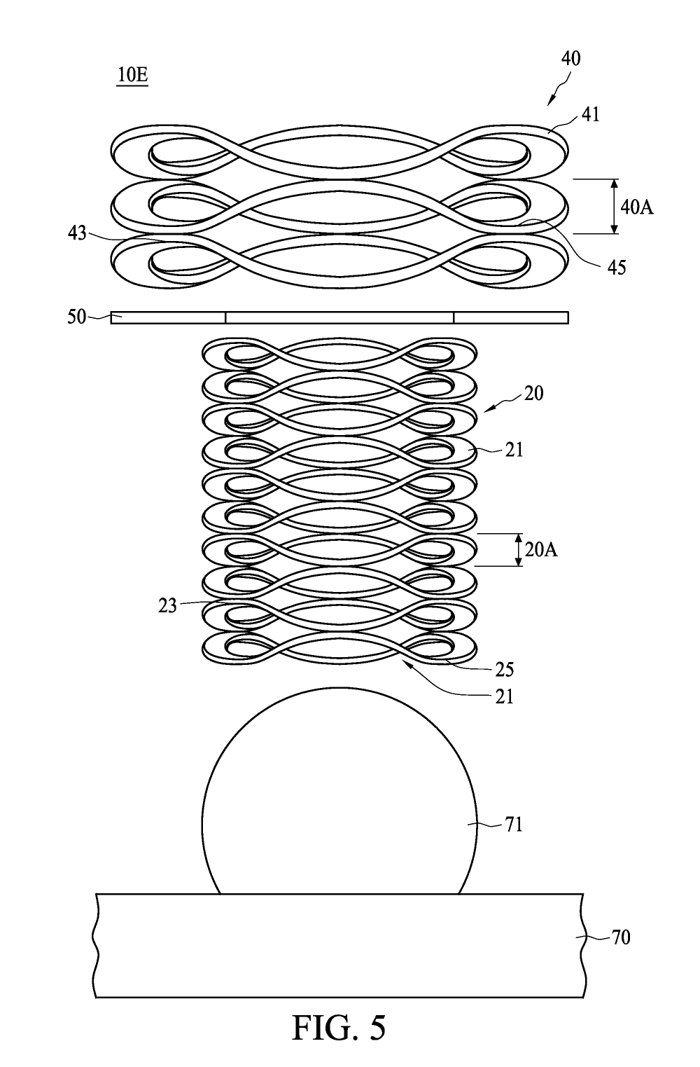

FIG. 5 illustrates a vertical probe 10E according to a fifth embodiment of the present invention. In one embodiment of the present invention, the vertical probe 10E comprises a bottom contact 20, a top contact 40 stacked on the bottom contact 20 in a substantially linear manner, and a washer 50 positioned between the bottom contact 20 and the top contact 40. In one embodiment of the present invention, the top contact 40 includes a plurality of wave springs 41 stacked one on top of another in a crest to crest manner. In one embodiment of the present invention, each of the wave springs 41 is formed from a single piece of conductive material, and comprises a plurality of upward crest portions 43 and downward trough portions 45, and the crest portions 43 abut the trough portions 25. In one embodiment of the present invention, the wave springs 41 in an uncompressed state have a wave height 40A, i.e., the distance between the upward crest portions 43 and the downward trough portions 45, which is configured to provide a vertical displacement for relieving the stress generated as the vertical probe 10E contacts the device under test 70 in a compressed state.

In one embodiment of the present invention, the bottom contact 20 has a bottom opening 21 configured to contact a ball 71 of a device under test 70. In one embodiment of the present invention, the bottom contact 20 includes a plurality of wave springs 21 stacked one on top of another in a crest to crest manner. In one embodiment of the present invention, each of the wave springs 21 is formed from a single piece of conductive material and comprises a plurality of upward crest portions 23 and downward trough portions 25, and the crest portions 23 abut the trough portions 25. In one embodiment of the present invention, the wave springs 21 in an uncompressed state have a wave height 20A, i.e., the distance between the upward crest portions 23 and the downward trough portions 25, which is configured to provide a vertical displacement for relieving the stress generated as the vertical probe 10E contacts the device under test 70 in a compressed state.

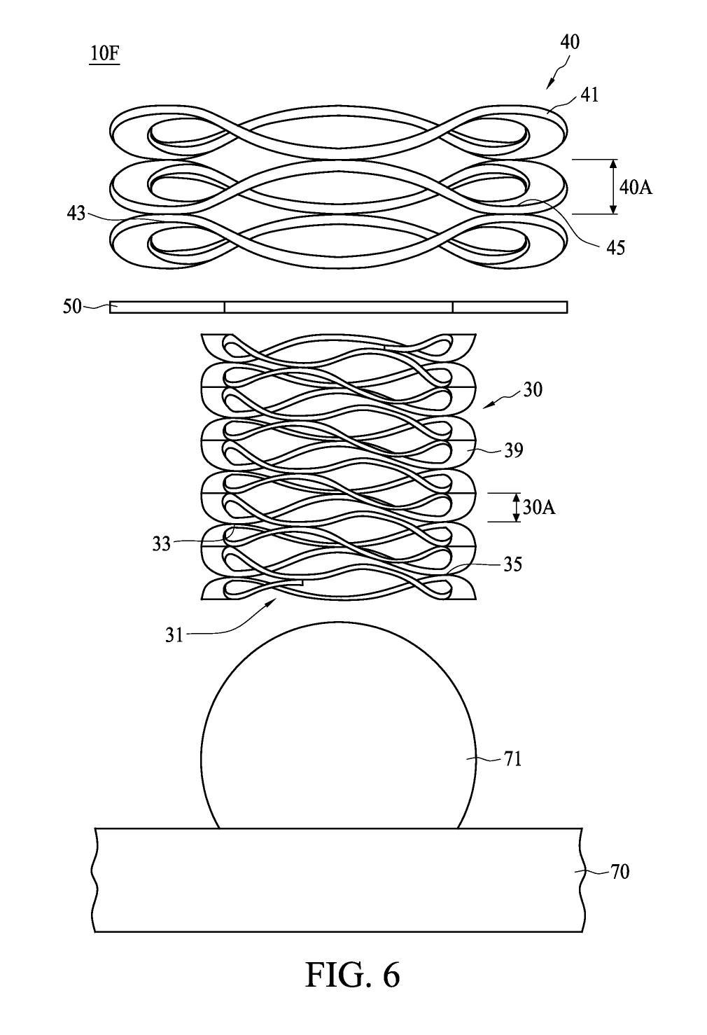

FIG. 6 illustrates a vertical probe 10F according to one embodiment of the present invention. In one embodiment of the present invention, the vertical probe 10F comprises a bottom contact 30, a top contact 40 stacked on the bottom contact 30 in a substantially linear manner, and a washer 50 positioned between the bottom contact 30 and the top contact 40. In one embodiment of the present invention, the top contact 40 includes a plurality of wave springs 41 stacked one on top of another in a crest to crest manner. In one embodiment of the present invention, each of the wave springs 41 is formed from a single piece of conductive material, and comprises a plurality of upward crest portions 43 and downward trough portions 45, and the crest portions 43 abut the trough portions 25. In one embodiment of the present invention, the wave springs 41 in an uncompressed state have a wave height 40A, i.e., the distance between the upward crest portions 43 and the downward trough portions 45, which is configured to provide a vertical displacement for relieving the stress generated as the vertical probe 10F contacts the device under test 70 in a compressed state.

In one embodiment of the present invention, the bottom contact 30 has a bottom opening 31 configured to contact a ball 71 of a device under test 70, and the width of the top contact 13 is greater than the width of the bottom contact 30. In one embodiment of the present invention, the bottom contact 30 is a wave spring formed from a single piece of conductive material and having a number of spring turns 39. In one embodiment of the present invention, each spring turn 39 has successive waves formed from distinct crest portions 33 and trough portions 35, and the crest portion 33 of one spring turn 39 abuts the trough portion 35. In one embodiment of the present invention, the wave spring 30 in an uncompressed state has a wave height 30A configured to provide a vertical displacement for relieving the stress generated as the vertical probe 10F contacts the device under test 70 in a compressed state.

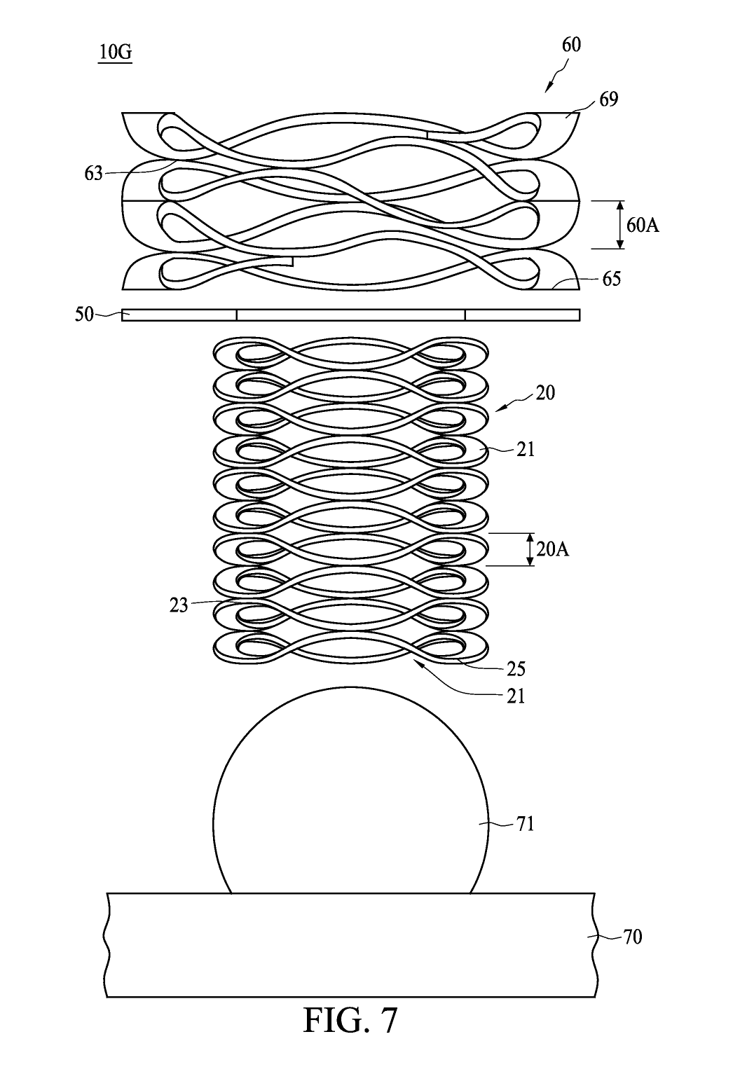

FIG. 7 illustrates a vertical probe 10G according to a seventh embodiment of the present invention. In one embodiment of the present invention, the vertical probe 10G comprises a bottom contact 20, a top contact 60 stacked on the bottom contact 20 in a substantially linear manner, and a washer 50 positioned between the bottom contact 20 and the top contact 60. In one embodiment of the present invention, the top contact 60 is a wave spring formed from a single piece of conductive material and having a number of spring turns 69. In one embodiment of the present invention, each spring turn 69 has successive waves formed from distinct crest portions 63 and trough portions 65, and the crest portion 63 of one spring turn 69 abuts the trough portion 65. In one embodiment of the present invention, the wave spring 60 in an uncompressed state has a wave height 60A configured to provide a vertical displacement for relieving the stress generated as the vertical probe 10G contacts the device under test 70 in a compressed state.

In one embodiment of the present invention, the bottom contact 20 has a bottom opening 21 configured to contact a ball 71 of a device under test 70, and the width of the top contact 11 is greater than the width of the bottom contact 20. In one embodiment of the present invention, the bottom contact 20 includes a plurality of wave springs 21 stacked one on top of another in a crest to crest manner. In one embodiment of the present invention, each of the wave springs 21 is formed from a single piece of conductive material and comprises a plurality of upward crest portions 23 and downward trough portions 25, and the crest portions 23 abut the trough portions 25. In one embodiment of the present invention, the wave springs 21 in an uncompressed state have a wave height 20A, i.e., the distance between the upward crest portions 23 and the downward trough portions 25, which is configured to provide a vertical displacement for relieving the stress generated as the vertical probe 10G contacts the device under test 70 in a compressed state.

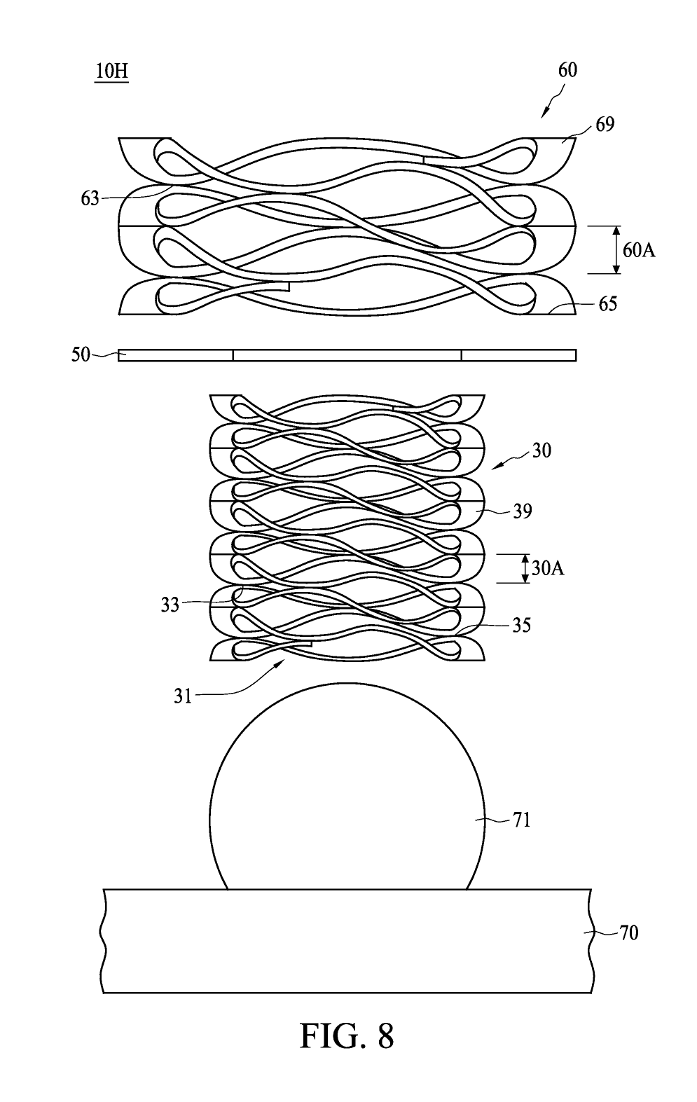

FIG. 8 illustrates a vertical probe 10H according to one embodiment of the present invention. In one embodiment of the present invention, the vertical probe 10G comprises a bottom contact 30, a top contact 60 stacked on the bottom contact 30 in a substantially linear manner, and a washer 50 positioned between the bottom contact 30 and the top contact 60. In one embodiment of the present invention, the top contact 60 is a wave spring formed from a single piece of conductive material and having a number of spring turns 69. In one embodiment of the present invention, each spring turn 69 has successive waves formed from distinct crest portions 63 and trough portions 65, and the crest portion 63 of one spring turn 69 abuts the trough portion 65. In one embodiment of the present invention, the wave spring 60 in an uncompressed state has a wave height 60A configured to provide a vertical displacement for relieving the stress generated as the vertical probe 10H contacts the device under test 70 in a compressed state.

In one embodiment of the present invention, the bottom contact 30 has a bottom opening 31 configured to contact a ball 71 of a device under test 70, and the width of the top contact 13 is greater than the width of the bottom contact 30. In one embodiment of the present invention, the bottom contact 30 is a wave spring formed from a single piece of conductive material and having a number of spring turns 39. In one embodiment of the present invention, each spring turn 39 has successive waves formed from distinct crest portions 33 and trough portions 35, and the crest portion 33 of one spring turn 39 abuts the trough portion 35. In one embodiment of the present invention, the wave spring 30 in an uncompressed state has a wave height 30A configured to provide a vertical displacement for relieving the stress generated as the vertical probe 10G contacts the device under test 70 in a compressed state.

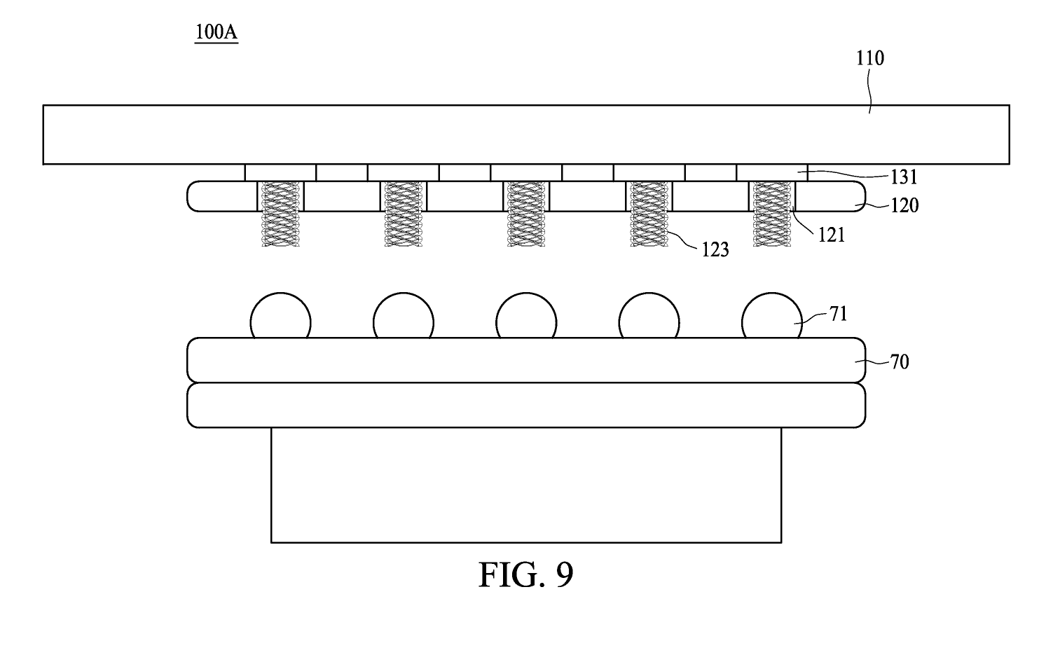

FIG. 9 illustrates a probe card 100A for semiconductor devices according to one embodiment of the present invention. In one embodiment of the present invention, the probe card 100A comprises a guiding member 120 having a plurality of holes 121, a circuit board 130 positioned on the guiding member 120, and a plurality of vertical probes 123 positioned in the holes 121 of the guiding member 120. In one embodiment of the present invention, the circuit board 130 has a plurality of contact sites 131 facing the holes 121 of the guiding member 120. In one embodiment of the present invention, each vertical probe 123 includes at least one wave spring configured to contact a ball 71 of a device under test 70, and the wave spring is configured to provide a vertical displacement for relieving the stress generated as the vertical probe 123 contacts a device under test 70. In one embodiment of the present invention, the vertical probe 123 is adhered to the contact sites 131 of the circuit board 110.

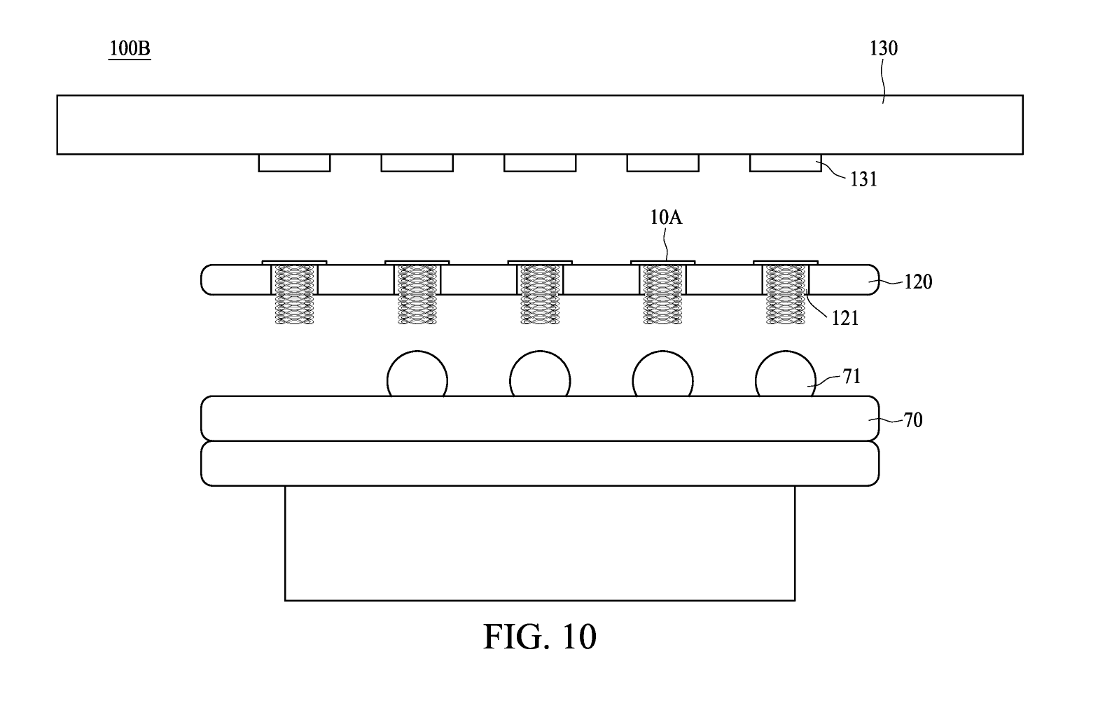

FIG. 10 illustrates a probe card 100B for semiconductor devices according to one embodiment of the present invention. In one embodiment of the present invention, the probe card 100B comprises a guiding member 120 having a plurality of holes 121, a circuit board 130 positioned on the guiding member 120, and a plurality of vertical probes 10A positioned in the holes 121 of the guiding member 120. In one embodiment of the present invention, the circuit board 130 has a plurality of contact sites 131 facing the holes 121 of the guiding member 120. Referring back to FIG. 1, the vertical probe 10A comprises a bottom contact 20 and a top contact 11 stacked on the bottom contact 20 in a substantially linear manner, the bottom contact 20 has a bottom opening 21 configured to contact a ball 71 of a device under test 70, and top contact 11 is configured to contact the contact sites 131 of the circuit board 130 so as to form a circuit channel between the circuit board 130 and the device under test 70. In addition, the width of the hole 121 is designed to be greater than the width of the bottom contact 20 and smaller than the width of the top contact 11. Consequently, the vertical probe 10A is positioned in the hole 121, instead of being adhered to the contact sites 131, and individual replacement of failed vertical probes 10A can be easily implemented.

The conventional vertical probe for semiconductor device such as the POGO pins uses the crown probe tip, which damages the solder ball of the device under test as the vertical probe contacts a device under test. For example, as a four-claw crown probe tip contacts the solder ball, a four-claw imprint is formed on the solder ball because the stress generated as the vertical probe contacts a device under test is applied to the small contact area.

In contrast, the disclosure of the present invention uses the wave spring with the bottom contact serving as the probe tip, and the wave spring contacts the solder ball with a larger ring-shaped contact area so as to reduce the damage of the vertical probe on the solder ball. In addition, the wave springs are stacked one on top of another in a crest to crest manner, the current can flow through the connected crest portions from one wave to another wave, i.e., there are multiple paths for the current, rather than a single coil flowing path, which will generate inductance effect and influence the electrical measurement.

The conventional cantilever probe cannot be applied to semiconductor devices with high-density pads since it requires a lateral space to receive the lateral cantilever. In contrast, the vertical probe for semiconductor device testing of the present application does not need the lateral space for the lateral cantilever, and can provide variable contact force and be applied to the semiconductor devices with high-density pads of very small pitch.

In addition, the conventional vertical probe for testing semiconductor devices uses the deformation of the probe body itself to provide the vertical displacement for relieving the stress generated as the probe contacts the device under test, but the adjacent probes may contact each other and cause short circuits or collisions if the deformation of the probe body is too large or there is minor misplacement of the probe body. In contrast, the vertical probe for semiconductor device testing of the present application uses the vertical wave height to relieve the stress substantially without a lateral displacement so as to prevent the vertical probes from contacting each other and causing short circuits or collisions.

Although the present invention and its advantages have been described in detail, it should be understood that various changes, substitutions and alterations can be made herein without departing from the spirit and scope of the invention as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A vertical probe for testing semiconductor devices, comprising:
a bottom contact including a plurality of first wave springs stacked one on top of another in a crest to crest manner, the bottom contact having a bottom opening configured to contact a device under test, and the wave spring being configured to provide a vertical displacement for relieving the stress generated as the vertical probe contacts the device under test; and
a top contact stacked on the bottom contact in a substantially linear manner, wherein the width of the top contact is greater than the width of the bottom contact.

2. The vertical probe for testing semiconductor devices of claim 1, wherein the bottom opening is configured to contact a ball of the device under test.

3. The vertical probe for testing semiconductor devices of claim 1, wherein the top contact includes a plurality of second wave springs stacked one on top of another in a crest to crest manner, and the width of the second wave springs is greater than the width of the first wave springs.

4. The vertical probe for testing semiconductor devices of claim 1, wherein the top contact includes a second wave spring having a plurality of spring turns, each spring turn includes at least one crest portion and at least one trough portion, and adjacent pairs of spring turns contact one another in a crest to crest manner.

5. The vertical probe for testing semiconductor devices of claim 1, further comprising a washer positioned between the bottom contact and the top contact.

6. The vertical probe for testing semiconductor devices of claim 1, wherein the top contact includes a contact portion on the bottom contact and a guiding portion in the bottom contact.

7. The vertical probe for testing semiconductor devices of claim 1, wherein the wave spring is configured to relieve the stress substantially without a lateral displacement.

8. A vertical probe for testing semiconductor devices, comprising:
a bottom contact including a first wave spring having a plurality of spring turns, each spring turn including at least one crest portion and at least one trough portion, adjacent pairs of spring turns contacting one another in a crest to crest manner, the first wave spring having a bottom opening configured to contact a device under test, and the first wave spring being configured to provide a vertical displacement for relieving the stress generated as the vertical probe contacts the device under test; and
a top contact stacked on the bottom contact in a substantially linear manner, the width of the top contact being greater than the width of the bottom contact.

9. The vertical probe for testing semiconductor devices of claim 8, wherein the bottom opening is configured to contact a ball of the device under test.

10. The vertical probe for testing semiconductor devices of claim 8, wherein the top contact includes a second wave spring having a plurality of spring turns, each spring turn includes at least one crest portion and at least one trough portion, and adjacent pairs of spring turns contact one another in a crest to crest manner.

11. The vertical probe for testing semiconductor devices of claim 8, wherein the top contact comprises a plurality of wave springs stacked one on top of another in a crest to crest manner.

12. The vertical probe for testing semiconductor devices of claim 8, further comprising a washer positioned between the bottom contact and the top contact.

13. The vertical probe for testing semiconductor devices of claim 8, wherein the top contact includes a contact portion on the bottom contact and a guiding portion in the bottom contact.

14. The vertical probe for testing semiconductor devices of claim 8, wherein the wave spring is configured to relieve the stress substantially without a lateral displacement.

15. A probe card for testing semiconductor devices, comprising:
a guiding member having a plurality of holes;
a circuit board positioned on the guiding member, the circuit board having a plurality of contact sites facing the holes; and
a plurality of vertical probes positioned in the holes, each vertical probe including a bottom contact having at least one wave spring configured to contact a device under test, the wave spring being configured to provide a vertical displacement for relieving the stress generated as the vertical probe contacts a device under test.

16. The probe card for testing semiconductor devices of claim 15, wherein the vertical probe comprises:
a bottom contact including a plurality of first wave springs stacked one on top of another in a crest to crest manner, and the bottom contact having a bottom opening configured to contact the device under test; and
a top contact stacked on the bottom contact in a substantially linear manner, and the width of the top contact being greater than the width of the bottom contact.

17. The probe card for testing semiconductor devices of claim 16, wherein the bottom opening is configured to contact a ball of the device under test.

18. The probe card for testing semiconductor devices of claim 16, wherein the top contact includes a plurality of second wave springs stacked one on top of another in a crest to crest manner, and the width of the second wave springs is greater than the width of the first wave springs.

19. The probe card for testing semiconductor devices of claim 16, wherein the top contact includes a second wave spring having a plurality of spring turns, each spring turn includes at least one crest portion and at least one trough portion, and adjacent pairs of spring turns contact one another in a crest to crest manner.

20. The probe card for testing semiconductor devices of claim 16, wherein the vertical probe further comprises a washer positioned between the bottom contact and the top contact.

21. The probe card for testing semiconductor devices of claim 16, wherein the top contact includes a contact portion on the bottom contact and a guiding portion in the bottom contact.

22. The probe card for testing semiconductor devices of claim 15, wherein the vertical probe comprises:
a bottom contact including a first wave spring having a plurality of spring turns, each spring turn including at least one crest portion and at least one trough portion, adjacent pairs of spring turns contacting one another in a crest to crest manner, and the first wave spring having a bottom opening configured to contact the device under test; and
a top contact stacked on the bottom contact in a substantially linear manner, the width of the top contact being greater than the width of the bottom contact.

23. The probe card for testing semiconductor devices of claim 22, wherein the bottom opening is configured to contact a ball of the device under test.

24. The probe card for testing semiconductor devices of claim 22, wherein the top contact includes a second wave spring having a plurality of spring turns, each spring turn includes at least one crest portion and at least one trough portion, and adjacent pairs of spring turns contact one another in a crest to crest manner.

25. The probe card for testing semiconductor devices of claim 22, wherein the top contact comprises a plurality of wave springs stacked one on top of another in a crest to crest manner.

26. The probe card for testing semiconductor devices of claim 22, wherein the vertical probe further comprises a washer positioned between the bottom contact and the top contact.

27. The probe card for testing semiconductor devices of claim 22, wherein the top contact includes a contact portion on the bottom contact and a guiding portion in the bottom contact.

28. The probe card for testing semiconductor devices of claim 15, wherein the wave spring is configured to relieve the stress substantially without a lateral displacement.
